(19) United States
(12) Patent Application Publication
(10) Pub. No.: US 2017/0016970 A1
(43) Pub. Date: Jan. 19, 2017

(54) MODULAR SYSTEM AND METHOD FOR FABRICATING A CONTROL COMPUTER OF A MAGNETIC RESONANCE APARATUS

(71) Applicant: Siemens Healthcare GmbH, Erlangen (DE)

(72) Inventor: Swen Campagna, Engelthal (DE)

(73) Assignee: Siemens Healthcare GmbH, Erlangen (DE)

(21) Appl. No.: 15/211,276

(22) Filed: Jul. 15, 2016

(30) Foreign Application Priority Data
Jul. 15, 2015 (DE) 102015213269.2

(51) Int. Cl. G01R 33/54

(52) U.S. Cl. CPC G01R 33/54

(57) ABSTRACT

A modular system is provided for fabricating a control computer for a selected magnetic resonance (MR) apparatus in a group of MR apparatuses having different design features. The modular system includes commonality modules for implementing functions that are identical for all MR apparatuses in the group, and scaling modules for implementing functions that can be provided to the required extent, dependent on the design features, for all MR apparatuses in the group. All modules have predefined interfaces to the other modules. The commonality modules and the scaling modules are each implemented as a hardware unit, and are combined with at least one variability module of the modular system implemented as a hardware unit designed specifically for the design features, to form a real-time unit of the control computer.

### BACKGROUND OF THE INVENTION

Field of the Invention

The invention concerns a modular system for fabricating a control computer, having a real-time unit implemented as hardware, for a magnetic resonance apparatus, and a method for fabricating a control computer for a magnetic resonance apparatus.

Description of the Prior Art

Implementing a control computer of a magnetic resonance apparatus is a complex task in a production process. The architecture of such a control computer may be based on many different types, and it is usual for the digital control of magnetic resonance apparatuses to be implemented in a dedicated and specific way in accordance with the requirements of a particular magnetic resonance apparatus, or of a product line composed of magnetic resonance apparatuses that have similar design features. The different, actualized implementations of control computers usually vary extremely widely in terms of their architecture, resulting in low reusability and correspondingly greater development cost for multiple different control computers. For example, in the case of control computers developed for inexpensive products, there is often a limit to the number of reception channels, etc.

Control computers for magnetic resonance apparatuses can be functionally reproduced, particularly when broken down according to the real-time requirements, as disclosed, for example, by DE 10 2012 215 722 A1. In that case, the breakdown is effected, by providing an MR measurement console, which does not have to satisfy any real-time requirement, and an MR measurement monitoring computer, which must satisfy soft real-time requirements on the order of one millisecond, as well as an MR controller, which may also be designated as a real-time unit. The MR controller ultimately implements the instructions issued by the MR measurement monitoring computer, in order to generate gradient fields with a gradient coil array, and to actuate radio-frequency transmission arrangements for radiating radio-frequency pulses, and reception units for receiving magnetic resonance signals, wherein peripheral components, such as shim assemblies, may also have to be actuated with precise timing. The MR controller or real-time unit must therefore satisfy real-time requirements in the order of one microsecond or even one nanosecond (hard real-time response). The MR controller immediately emits signals to the independent magnetic resonance apparatus components to be actuated, which may also be designated as being in the “immediate time” domain.

Expressed in purely functional terms, it may also be said that real-time requirements are not necessary for functions for planning a measurement or for reconstructing magnetic resonance images, while in the soft real-time domain, for example in a drive-measurement function, the exact sequence of the magnetic resonance measurement can be defined dynamically and in technical detail, and can be received, in corresponding chronological order accordingly, in a function for receiving measurement data. The hard real-time domain, usually implemented by the real-time unit as hardware components, can be functionally described as “execute and control”.

By the “execute and control” function, the deterministic instructions that were defined on the part of the soft real-time components are implemented and the exact compliance with the relative time intervals of the independent, downstream units is realized.

### SUMMARY OF THE INVENTION

An object of the invention is to provide a facility for fabricating control computers for magnetic resonance apparatuses based on a modular system, which can be used for a great many different magnetic resonance apparatuses that are described by different design features, and which offers a high level of reusability for the individual modules.

This object is achieved according to the invention by a modular system for fabricating, for a magnetic resonance apparatus, a control computer having a real-time unit implemented as hardware, from a group of possible magnetic resonance apparatuses having different design features. The modular system comprising has commonality modules for implementing functions that identical for all magnetic resonance apparatuses in the group, which have predefined interfaces to further modules of the control computer, and scaling modules for implementing functions that can be provided to the required extent for all magnetic resonance apparatuses in the group, to a different degree as required by the design features, by a number of scaling modules in a control computer, wherein the scaling modules have predefined interfaces to further modules of the control computer. The commonality modules and the scaling modules are each implemented as a hardware unit, and a commonality module and a number of scaling modules—the number depending on the extent required—can be combined with at least one variability module implemented as a hardware unit specifically for the design features, to form the real-time unit.

The variability module also expediently has predefined interfaces to further modules of the control computer and may itself form part of the modular system. The modules of the real-time unit may, of course, also have already standardized interfaces to actuated components of the magnetic resonance apparatus.

The inventive method is based on a definition of an abstract architecture for the digital control of a magnetic resonance apparatus, which pursues a completely new approach designed for maximum reusability and the widest possible applicability. In particular, the abstract architecture is intended to be able to implement ranges of functions that are conceivable and planned and are described by the group of magnetic resonance apparatuses, and at the same time (by omission) to contain only precisely those parts which are necessary in the minimal case. Going beyond the basic idea, to classify abstract function units into various necessary time requirements the present invention focuses on the parts that implement hard, real-time requirements and can usually only be satisfied by hardware, for example FPGAs. In this context, the functionalities are now identified that are identical for all magnetic resonance apparatuses in the group, i.e. conceivable combinations of design features (commonality). Functions are also identified that must be scalable within the group, for example the number of reception channels (scalability). Finally, this leaves the parts that vary within the group of magnetic resonance apparatuses and must therefore be based on the particular design features of individual apparatuses in the group. From information thus obtained, it is now possible to assign functions to modules of the digital controller, in this case the hard real-time part of the digital controller, making cost-effective yet flexible control possible.

An important feature of the inventive development is that it is precisely the parts/functions with high variability that are concentrated in one or a few modules, i.e. variability modules, and only these must be developed with multiple individual variants. Moreover, it is precisely the parts/functions with high necessary scalability that are isolated, and their scalability is ensured by reusing scaling modules that are all identically configured. The parts with very high commonality are architecturally identical, so that the highest level of reusability is present during development, so that there is therefore only one technical form (embodiment) for the commonality module.

Thus a suitably modularized, adaptable control architecture, which both makes control computers cost-effective for low-end magnetic resonance apparatuses while at the same time supporting higher-grade magnetic resonance apparatuses up to the high-end and research field, is provided for the first time. For a magnetic resonance apparatus with specific design features, it is necessary only for precisely those parts that are exactly relevant for those features to be implemented in the form of new variability modules. An extremely high level of reusability is therefore present in existing modules, so the development of new variability modules is greatly simplified because an existing and supporting system architecture is already present. By a unique interface definition, actuation is made far easier due to higher control layers—whether software layers or hardware layers—satisfying lower real-time requirements, so that the same higher levels can be used in exactly the same way as the same commonality modules and scaling modules, particularly across different product lines.

Structural uniformity, even in the event of multiple implementation due to a varying quantity of scalability modules, considerably increases the maintainability of control computers, since their functioning within the external interfaces of the digital magnetic resonance controller is essentially identical, but also since the aforementioned external interfaces are identical and these interfaces can actuate the identical components outside.

An abstraction according to commonality, scalability and variability, particularly in the context of magnetic resonance apparatuses has been found to result in an extremely expedient distribution, which ensures a high level of reusability. Thus it has been found that, because magnetic resonance apparatuses generally operate with measurement sequences (magnetic resonance sequences), it is not only the central coordination, which receives and converts sequence commands as instructions of a superordinate module, but also radio-frequency transmit processes and the actuation of gradient coils, that are to be regarded and implemented as being essentially communal for all magnetic resonance apparatuses. In an embodiment of the invention, therefore, the commonality modules, in an integrated implementation, have the following: a central coordination component, which is configured for receiving sequence commands describing a measurement sequence, a radio-frequency transmission component for actuating a radio-frequency transmission arrangement according to the sequence commands, and a gradient coil control component for actuating a gradient coil array according to the sequence commands. The integrated implementation means that the commonality module is a hardware unit, for example a plug-in card or similar, in which the individual components can be implemented, for example, as FPGAs or similar.

It has been found to be expedient if the commonality modules also have, in the integrated implementation, a timing component for the timing of actuation processes according to the sequence commands. Magnetic resonance apparatuses essentially require time coordination, which ensures the exact relative timing of the thereafter completely independent signal paths upon the transition between the hard real time and the “immediate time” time domains. While it has been conventional for this functionality to be implemented as a separate or distributed unit, for example implemented via a dedicated communication network, the time coordination and therefore the timing is essentially communal for all magnetic resonance apparatuses, so that it may be advantageous to implement this as a component of the commonality modules, in order, therefore, also to be able to cover in particular cost-effective low-end magnetic resonance apparatuses in the group.

In another embodiment of the invention, the scaling modules, or at least one type thereof, are configured as reception modules for receiving magnetic resonance signals during the measurement sequence.

Magnetic resonance apparatuses exist in various embodiments, in which a wide range of the possible number of reception channels must be covered. This fact is taken into account in the embodiment wherein reception modules are provided as scaling modules. The greater the number of reception channels that are present on a specific magnetic resonance apparatus that is to be equipped, the greater the number of reception modules that can be used.

The greatest variability factor, when considering magnetic resonance apparatuses with different design features in the group, is still peripheral components. The term “peripherals” means any, usually individual, aspect of a magnetic resonance apparatus, such as actuators for the patient bed, shim devices, communication devices for the patient, EKG measurement equipment, etc. Peripheral components of this kind may have different time domain requirements and may be implemented in different formats, resulting in the many design features. If the group of magnetic resonance apparatuses is clearly defined, provision can be made for the modular system additionally to have variability modules for all members of the group, which are configured for actuating peripheral devices in magnetic resonance apparatuses. The variability modules, as noted, are therefore the only parts of the real-time unit (and especially also of the entire control computer), which must be dedicatedly developed on the basis of specific design features. Variability modules as hardware units may be implemented, for example, as so-called COM boxes, which may be composed of separate components in a computation unit. This separation is particularly useful when a high level of variability is to be expected between different magnetic resonance apparatuses or magnetic resonance platforms, so that variability modules in hardware and in firmware can be adapted separately to the simplest one, without these adaptations affecting other modules. Provision may be made for separate variability modules, that can be used in a single control computer, which are allocated (for example) to a control room and the radio-frequency shield enclosure, respectively, and situated at those respective locations.

A control computer for a specific magnetic resonance apparatus is preferably completed by suitable software modules, which link to corresponding external interfaces of the real-time unit, such as result from the predefined interfaces of the modules used therein. In a preferred embodiment, therefore the modular system further has, via some of the interfaces, software modules that can be connected to the real-time unit and that are identical for all magnetic resonance apparatuses in the group. Since the variability and the scaling are mapped to the corresponding modules, it is also possible to provide a common software environment for all magnetic resonance apparatuses in the group, which can easily be configured according to design features if required. The software modules are preferably configured in order to determine a measurement sequence and measurement sequence commands from a measurement instruction and to evaluate received measurement signals provided via the real-time unit. In other words, the software modules may also have a planning component for planning and/or sequencing a magnetic resonance measurement and an action component for defining a sequence for the magnetic resonance measurement, and thus for determining the measurement sequence and the sequence commands. It is also possible for individual, interacting software modules to be created for such functions and further functions.

A planning component thus ultimately maps the part of the digital control of a magnetic resonance apparatus that functions without real-time requirements. As a result, the planning and/or sequencing of a magnetic resonance measurement is made possible in the same way as the ultimate reconstruction and reproduction/further processing of magnetic resonance images. By the use of an action component for defining a sequence for the magnetic resonance measurement, the exact sequence of the measurement can be defined as the measurement sequence with assigned measurement commands, dynamically and with a high level of technical detail. A magnetic resonance sequence can include, for example, the exact chronological sequence of at least one radio-frequency pulse and/or at least one gradient pulse, wherein measurement phases, and thus readout times of corresponding reception components, are also included. An action component may respond to feedback from an image reconstruction component, but also to measured, physiological signals. It therefore has real-time requirements in the order of one millisecond (“soft real time”). The implementation of the action component is therefore possible through software, as is preferred. In this context, as noted above, the real-time unit, as a central control component, is understood as executing the instructions of the action component.

An advantageous implementation of the commonality modules and of the scaling modules as hardware units is achieved when the commonality modules and the scaling modules are configured as plug-in cards for computation units. A highly integral control computer for a magnetic resonance apparatus can be fabricated if the software modules are installed on the computation unit. With regard to the variability modules, it is of course also possible in principle for these to be implemented partially as plug-in cards for the computation unit, so that a compact development of an overall control computer can ultimately be created with a single computation unit, the software modules being installed thereon and the real-time unit being created by plugging in the corresponding plug-in cards. However, at least for some of the variability modules, where these components must be actuated locally in the radio-frequency cabin, external implementation is often still possible, for example via a COM box as mentioned above. It should be noted that the computation unit, especially for low-end magnetic resonance apparatuses, can be formed using a commercially available PC.

As well as the modular system, the present invention also relates to a method for fabricating a control computer that has a real-time unit implemented as hardware, for a magnetic resonance apparatus having design features, using a modular system of the inventive type that includes the following steps.

A commonality module that is not detected by the design features.

Scaling modules are selected and provided that are not dictated in design by the design features, but the number of scaling modules is dependent on the design features.

A variability module is selected and provided depending on the design features.

A real-time unit is assembled from the provided modules. By combining it with at least one module covering the non-real-time domain and one covering the soft real-time domain, in particular a software module already discussed, the operational control computer is then produced. All embodiments relating to the modular system are applicable to the inventive method.

Therefore, a commonality module is used, of which only a single technical variant is required and which, preferably in addition to the central coordination, preferably contains the components that are always required for the gradient fields and the radio-frequency fields. Depending on how many reception channels the magnetic resonance apparatus is to be able to use, for which the control computer is to be fabricated, a corresponding number of scaling modules is selected, which in turn exist only in an actualized embodiment, and are, in particular, reception modules. The variability of the design features is then reflected mainly in the variability modules, which are additionally selected on the basis of the specific design features of the magnetic resonance apparatus for which the control computer is to be fabricated, in order to obtain the real-time unit by the assembly of commonality module, at least one scaling module and at least one variability module. For a clearly defined group of magnetic resonance apparatuses, correspondingly developed variability modules that cover the wide variety of design features can also be part of the modular system. It is also expedient if the software modules covering the planning and actual implementation phase are already part of the modular system, so that, by combining them with at least one software module, which is also identical for all magnetic resonance apparatuses in the group, the control computer is created. For example, the software module can be installed on a computation unit, into which the commonality module and the at least one scaling module can be plugged in as plug-in cards. Furthermore, the at least one variability module can also be connected to the computation unit, via a corresponding communication link in the case of an external embodiment.

### BRIEF DESCRIPTION OF THE DRAWINGS

FIG. 1 shows the basic architecture of a control computer, which can be fabricated according to the invention.

FIG. 2 schematically illustrates an inventive modular system.

FIG. 3 shows a first concrete embodiment of a control computer for a first magnetic resonance apparatus.

FIG. 4 shows a second concrete embodiment of a control computer for a second magnetic resonance apparatus.

### DESCRIPTION OF THE PREFERRED EMBODIMENTS

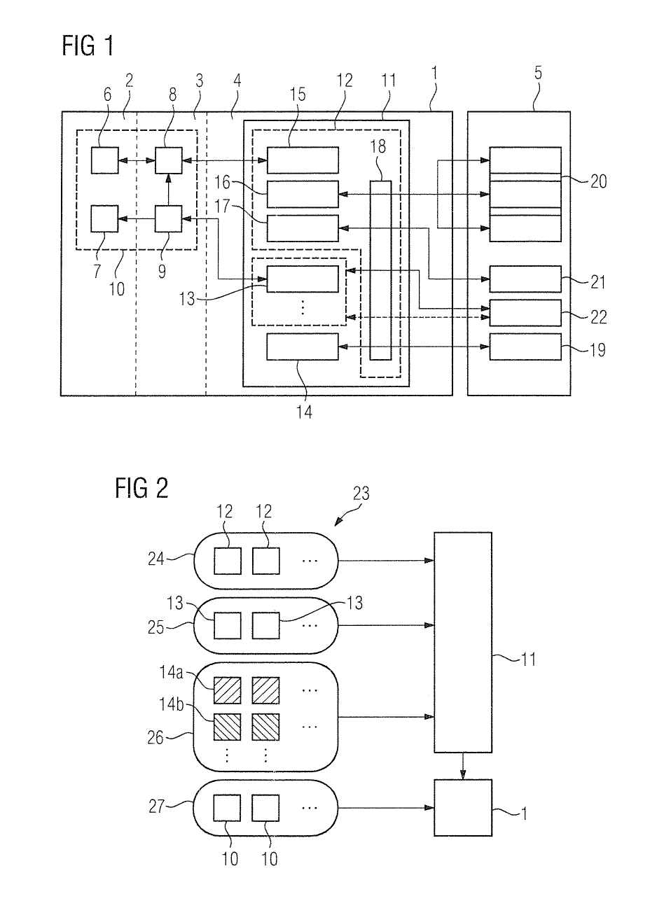

FIG. 1 shows the system architecture of a control computer 1 of a magnetic resonance apparatus. The control computer can be fabricated according to the invention with different detail, starting from an abstract level, which is the basis of the inventive method. In the digital control of a magnetic resonance apparatus, it is generally necessary to differentiate between different time domains, i.e. a domain 2 without real-time requirements, a domain 3 with soft real-time requirements and a domain 4 with hard real-time requirements in the microsecond and especially nanosecond range. The hardware 5 to be actuated via independent signal paths is in the so-called “immediate time” time domain. The dividing lines shown are to be considered as merely schematic, since the boundaries shown between the time domains many also be located inside components, so that only the main allocation of individual components of the control computer 1 is to be illustrated here.

In the domain 2 without real-time requirements, the planning of a measurement and the reconstruction of a magnetic resonance image are shown here as exemplary components by the box 6 and the box 7 respectively. In the soft real-time domain 3, the box 8 signifies the function for converting a measurement instruction into actual sequence commands, while the box 9 is meant to symbolize the receipt of measurement data. The functions indicated by the boxes 6 to 9 and other functions not illustrated in further detail here are implemented by a common software module 10 in the present case.

The function of the box 6 is used for planning and ordering a magnetic resonance measurement and has no real-time requirements. The function of the box 8 (“drive measurement”) defines dynamically and in technical detail the exact sequence of the magnetic resonance measurement, and therefore relates to the selection and development of the measurement sequences, which are reflected in concrete instructions, i.e. sequence commands. The function responds to feedback, for example from the image reconstruction, or to physiological signals and therefore has soft real-time requirements in the order of one millisecond.

To be able to convert the above-mentioned sequence commands, a real-time unit 11 covering the hard real-time domain 4 is provided as the central control component. For the purpose of achieving maximum reusability, this is subdivided into modules: in this case a commonality module 12, one or more scaling modules 13 and a variability module 14. The commonality module 12 contains all functionalities which are similarly required for all magnetic resonance apparatuses, so that, in a modular system from which the control computer 1 was fabricated, only a single concrete technical embodiment of the commonality module 12 is required. The commonality module 12 is implemented as a hardware unit, in particular a plug-in card for a computation unit. This is implemented firstly by a central coordination component 15, which takes over central functions that are not possible or feasible locally in the respective signal path (for example B0 correction), but also receives sequence commands centrally and preprocesses them if necessary. The commonality module 12 further comprises, in an integrated design, a gradient coil control component 16, via which three gradient channels X/Y/Z always present in a commercially available magnetic resonance apparatus can be operated. The commonality module 12 also comprises a radio-frequency transmission component 17, which may also be known as a TX unit. This operates the typically one radio-frequency transmission channel.

In the illustrated exemplary embodiment, the commonality module 12 also implements a timing component 18, since implementing the time coordination is essential in the architecture shown here. The timing component 18 ensures the exact relative timing upon the transition between the hard real-time and the “immediate time” of the thereafter completely independent signal paths.

The reception operation is controlled by the at least one scaling module 13 implemented as a receive model, which thus forms the RX unit. The at least one scaling module 13 therefore receives the digitized data stream of what is usually a multitude of reception channels and prepares it in such a way that it can be further processed with a lower real-time requirement, i.e. particularly in software.

Finally, the real-time unit 11 also contains at least one variability module 14, which is designed in this case as a peripheral unit for actuating peripheral devices in the magnetic resonance apparatus. The variability module 14 is responsible for every other (and usually quite individual) aspects of the magnetic resonance apparatus, for example actuators for the patient couch, shim devices, devices for communicating with the patient, EKG measurement equipment and such like. It should be mentioned here that, even though the control arrow to the peripheral devices 19 indicated in the hardware 5 is shown going through the timing component 18, the peripheral devices 19 can be actuated by the variability module 14 in many different time-domain requirements.

Additionally indicated within the hardware 5 are a three-channel gradient coil array 20, a radio-frequency transmission arrangement 21 and a reception arrangement 22.

In summary the real-time unit 11, whose function can be described as “execute and control,” executes the sequence commands received from the software module 10 and ensures exact compliance with the relative timing of the independent signal paths/components to one another.

Based on this architecture, FIG. 2 is a schematic illustration of a modular system 23 for fabricating a control computer 1 of a magnetic resonance apparatus. With the modular system 23, it should be possible for a group of different magnetic resonance apparatuses, which therefore have different design features, to fabricate control computers 1 with the highest possible proportion of recyclable parts. For this purpose, the modular system 23 firstly contains a quantity 24 of commonality modules 12, which are all designed identically and are suitable for implementing the corresponding functions in each of the magnetic resonance apparatuses in the group. The commonality modules 12 are therefore all identical.

The modular system 23 further has a quantity 25 of scaling modules 13, likewise all identically configured, of which a plurality, in this case dependent on the number of reception channels, can be used in the control computer 1.

One quantity 26 contains variability modules 14a, 14b, etc., which have been dedicatedly designed for specific design features of magnetic resonance apparatuses. These variability modules 14a, 14b, etc. cover the possible embodiments of the group of magnetic resonance apparatuses.

Finally, the modular system 23 contains, in a group 27, a further software module 10, which can be configured and copied as required, and which—on the basis of the predefined interfaces, and thus also predefined external interfaces, of modules 12, 13 and 14a, 14b, etc.—can be used for all combinations of modules 12, 13, 14a, 14b, etc.

In specific terms this means that, in order to fabricate a control computer 1, exactly one commonality module 12 is provided first. Then a number of scaling modules 13, dependent on the reception channels of the magnetic resonance apparatus, i.e. of a design feature, are provided, so that the number of reception channels of the magnetic resonance apparatus can be handled. Finally, depending on the design features of the specific magnetic resonance apparatus, at least one variability module 14a, 14b, etc. is selected. The selected/provided modules 12, 13, 14a, 14b, etc. thus form the real-time unit 11. If these are now combined with a software module 10, which is to be configured accordingly as required, the control computer 1 is produced. For example, the software module 10 can be installed on a computation unit, into which the commonality module 12 and the at least one scaling module 13 are plugged as plug-in cards, and with which the at least one variability module 14a, 14b, etc. is connected via at least one communication link.

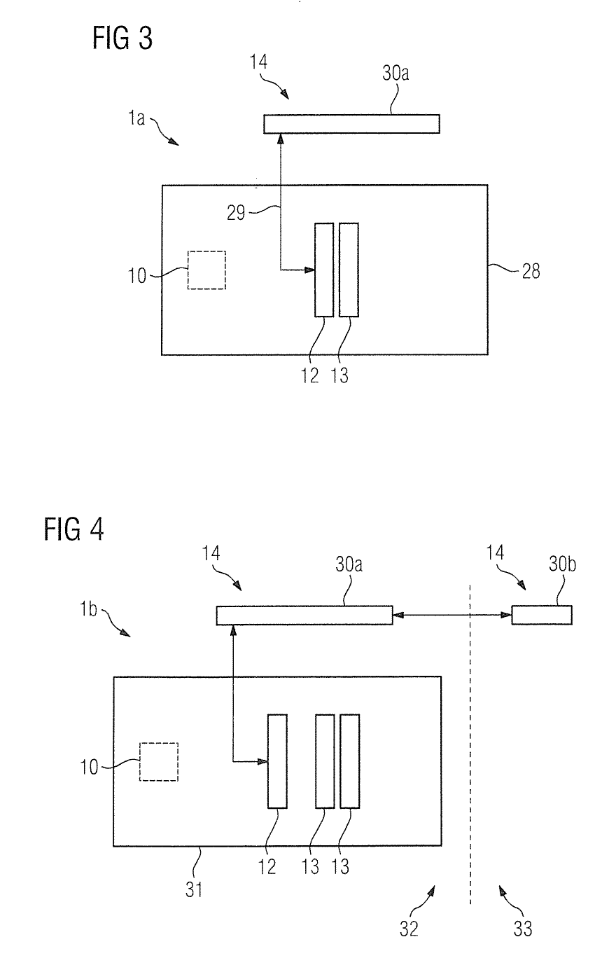

FIG. 3 shows a control computer 1a, as can be implemented for a low-end magnetic resonance apparatus by the modular system 23. The control computer 1a has a computation unit 28, in this case a normal PC, on which the software module 10 is installed, which covers the domain 2 without real-time requirements and the domain 3 of the soft real-time requirements. The commonality module 12 implemented as a plug-in card uses the infrastructure (power, housing and communication) of the computation unit 28 directly. Since the number of reception channels is rather low, in this case only one scaling module 13, which is likewise implemented as a plug-in card, is provided as a reception module.

The variability module 14 connected to the computation unit 28 via a communication link 29 is implemented in this case as a separate COM box 30.

FIG. 4 shows a control computer 1b, as may be fabricated for a more expensive magnetic resonance apparatus provided with additional equipment features. The computation unit 31 used in this case offers greater computing power; the software module 10 is in turn installed on it. The commonality module 12 is unchanged with regard to the control computer 1a, but a further scaling module 13 has been added since a larger number of reception channels are to be handled. Two variability modules 14 are also present in this case, implemented by COM boxes 30a and 30b, the COM box 30a being arranged in an engineering room 32 in exactly the same way as the computation unit 31; the COM box 30b, however, being inside the radio-frequency cabin 33 of the magnetic resonance facility in which the magnetic resonance apparatus is used.

It should also be noted that the software component 10 may of course also be implemented as a distributed software package on a number of computation units, for example a console computer and a control computer.

Although modifications and changes may be suggested by those skilled in the art, it is the intention of the inventor to embody within the patent warranted hereon all changes and modifications as reasonably and properly come within the scope of his contribution to the art.

I claim as my invention:

1. A modular system for fabricating a control computer for operating a selected magnetic resonance apparatus among a group of magnetic resonance apparatuses respectively having different design features, said control computer comprising a real-time unit implemented as hardware, said modular system comprising:
a plurality of commonality modules each configured to implement functions that are identical for all of the magnetic resonance apparatuses in the group, and that each have predetermined interfaces to further modules of the control computer;
a plurality of scaling modules, each scaling module being configured to implement a function that is the same for all of said magnetic resonance apparatuses in said group but that differs in degree among said magnetic resonance apparatuses in said group, each scaling module having a predetermined interface to further modules in said control computer;
a plurality of variability modules that each configure to implement a function that is not the same for any of said magnetic resonance apparatuses in said group; and
said commonality modules, said scaling modules and said variability modules being configured for selective combination as hardware units to form said real time unit of said control computer for the selected magnetic resonance apparatus, with said commonality modules, said scaling modules and said variability modules being respectively selected in number so as to cause all of the respective design features for the selected magnetic apparatus to be implemented by said real time unit.

2. A modular system as claimed in claim 1 wherein each of said commonality modules comprises:
a central coordination component configured to receive sequence commands that describe a magnetic resonance measurement sequence;
a radio-frequency transmission component configured to actuate a radio-frequency transmission arrangement of magnetic resonance apparatuses in said group, according to said sequence commands; and
a gradient coil control component configured to actuate a gradient coil array in said magnetic resonance apparatuses in said group according to said sequence commands.

3. A modular system as claimed in claim 1 wherein each commonality module comprises a timing component configured to time actuation of events in said magnetic resonance measurement sequence according to said sequence commands.

4. A modular system as claimed in claim 1 wherein at least one of said scaling modules is configured as a reception module for receiving magnetic resonance signals during a magnetic resonance measurement sequence.

5. A modular system as claimed in claim 1 wherein said variability modules include a variability module that is configured to actuate peripheral devices for all magnetic resonance apparatuses in said group.

6. A modular system as claimed in claim 1 wherein at least some of said interfaces are configured to produce a connection of a software module to said real time unit, said some of said interfaces being identical for all of the magnetic resonance apparatuses in the group.

7. A modular system as claimed in claim 6 wherein said software modules are configured to determine a magnetic resonance measurement sequence and measurement sequence commands from measurement instructions.

8. A modular system as claimed in claim 6 wherein said software modules are configured to evaluate received magnetic resonance measurement signals provided thereto via the real time unit.

9. A modular system as claimed in claim 1 wherein each of said commonality modules and said scaling modules is a plug-in card for said computer.

10. A modular system as claimed in claim 8 wherein at least some of said interfaces are configured to produce a connection of a software module to said real time unit, said some of said interfaces being identical for all of the magnetic resonance apparatuses in the group and wherein said software modules are installed in said computer.

11. A method system for fabricating a control computer for operating a selected magnetic resonance apparatus among a group of magnetic resonance apparatuses respectively having different design features, said control computer comprising a real-time unit implemented as hardware, said modular system comprising:
providing a plurality of commonality modules each configured to implement functions that are identical for all of the magnetic resonance apparatuses in the group, and that each have predetermined interfaces to further modules of the control computer;
providing a plurality of scaling modules, each scaling module being configured to implement a function that is the same for all of said magnetic resonance apparatuses in said group but that differs in degree among said magnetic resonance apparatuses in said group, each scaling module having a predetermined interface to further modules in said control computer;
providing a plurality of variability modules that each configure to implement a function that is not the same for any of said magnetic resonance apparatuses in said group; and
selectively combining individual modules among said commonality modules, said scaling modules and said variability modules in a configuration to form said real time unit of said control computer for the selected magnetic resonance apparatus, by selecting said commonality modules, said scaling modules and said variability modules in number so as to cause all of the respective design features for the selected magnetic apparatus to be implemented by said real time unit.
